(19) United States
(12) Patent Application Publication
(10) Pub. No.: US 2024/0290861 A1
(43) Pub. Date: Aug. 29, 2024

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP); Masahiro WATABE, Tokyo (JP)

(21) Appl. No.: 18/435,094

(22) Filed: Feb. 7, 2024

(30) Foreign Application Priority Data
Feb. 27, 2023 (JP) 2023-028476

(51) Int. Cl. H01L 29/49; H01L 29/66; H01L 29/786

(52) U.S. Cl. CPC H01L 29/4908; H01L 29/66969; H01L 29/78648; H01L 29/7869

(57) ABSTRACT

A semiconductor device according to an embodiment includes: a first gate electrode; a first insulating layer on the first gate electrode; an oxide semiconductor layer on the first insulating layer; a second insulating layer on the oxide semiconductor layer; and a second gate electrode on the second insulating layer. The first insulating layer includes a first layer including silicon and nitrogen, a second layer including silicon and oxygen, and a third layer including aluminum and oxygen. A thickness of the first layer is 10 nm or more and 190 nm or less. A thickness of the second layer is 10 nm or more and 100 nm or less. A total thickness of the first layer and the second layer is 200 nm or less. A thickness of the third layer 1 nm or more and 10 nm or less.

### CROSS REFERENCE TO RELATED APPLICATIONS

This application claims the benefit of priority to Japanese Patent Application No. 2023-028476, filed on Feb. 27, 2023, the entire contents of which are incorporated herein by reference.

### FIELD

An embodiment of the present invention relates to a semiconductor device using an oxide semiconductor for a channel.

### BACKGROUND

In recent years, a semiconductor device in which an oxide semiconductor is used for a channel instead of silicon semiconductors such as amorphous silicon, low-temperature polysilicon, and single-crystal silicon has been developed (for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device including such an oxide semiconductor can be formed with a simple structure and a low-temperature process, similar to a thin film transistor containing amorphous silicon. The semiconductor device containing the oxide semiconductor is known to have higher field-effect mobility than the semiconductor device containing amorphous silicon.

In the semiconductor device in which the oxide semiconductor is used for the channel, an electrical characteristic may vary due to electrons or holes being trapped in an insulating layer arranged above or below an oxide semiconductor layer in a stress test. In particular, there is a problem in that the electrical characteristics of the semiconductor device are shifted in a negative voltage direction by a reliability test in which a negative stress voltage is applied to a gate electrode of the semiconductor device while the semiconductor device is irradiated with light.

### SUMMARY

A semiconductor device according to an embodiment of the present invention includes: a first gate electrode; a first insulating layer on the first gate electrode; an oxide semiconductor layer on the first insulating layer; a second insulating layer on the oxide semiconductor layer; and a second gate electrode on the second insulating layer. The first insulating layer includes a first layer including silicon and nitrogen, a second layer including silicon and oxygen, and a third layer including aluminum and oxygen. A thickness of the first layer is 10 nm or more and 190 nm or less. A thickness of the second layer is 10 nm or more and 100 nm or less. A total thickness of the first layer and the second layer is 200 nm or less. A thickness of the third layer 1 nm or more and 10 nm or less.

### BRIEF DESCRIPTION OF DRAWINGS

FIG. 1 is a cross-sectional view showing an outline of a semiconductor device according to an embodiment of the present invention.

FIG. 2 is a plan view showing an outline of a semiconductor device according to an embodiment of the present invention.

FIG. 3 is a diagram showing electrical characteristics of a semiconductor device according to an embodiment of the present invention.

FIG. 4 is a diagram showing a threshold voltage calculated from electrical characteristics of a semiconductor device according to an embodiment of the present invention.

FIG. 5 is a diagram showing mobility calculated from electrical characteristics of a semiconductor device according to an embodiment of the present invention.

FIG. 6 is a diagram showing electrical characteristics before and after a stress test of a semiconductor device according to an embodiment of the present invention.

FIG. 7 is a diagram showing electrical characteristics before and after a stress test of a semiconductor device according to an embodiment of the present invention.

FIG. 8 is a diagram showing a variation in a threshold voltage calculated from electrical characteristics before and after the stress tests of a semiconductor device according to an embodiment of the present invention.

FIG. 9 is a sequence diagram showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a cross-sectional view showing a method for manufacturing a semiconductor device according to an embodiment of the present invention.

FIG. 14 is a cross-sectional view showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing a method for manufacturing a semiconductor device according to an embodiment of the present invention.

FIG. 18 is a plan view showing an outline of a display device according to an embodiment of the present invention.

FIG. 19 is a block diagram showing a circuit configuration of a display device according to an embodiment of the present invention.

FIG. 20 is a circuit diagram showing a pixel circuit of a display device according to an embodiment of the present invention.

FIG. 21 is a cross-sectional view showing an outline of a display device according to an embodiment of the present invention.

FIG. 22 is a plan view of a pixel electrode and a common electrode of a display device according to an embodiment of the present invention.

FIG. 23 is a circuit diagram showing a pixel circuit of a display device according to an embodiment of the present invention.

FIG. 24 is a cross-sectional view showing an outline of a display device according to an embodiment of the present invention.

### DESCRIPTION OF EMBODIMENTS

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

In the embodiments of the present invention, a direction from a substrate to an oxide semiconductor layer is referred to as “on” or “above”. Reversely, a direction from the oxide semiconductor layer to the substrate is referred to as “under” or “below”. As described above, for convenience of explanation, although the phrase “above (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, and in the case where it is expressed as a pixel electrode above a transistor, it may be a positional relationship where the transistor and the pixel electrode do not overlap each other in a plan view. On the other hand, in the case where it is expressed as a pixel electrode vertically above a transistor, it means a positional relationship where the transistor and the pixel electrode overlap each other in a plan view.

In this specification, the terms “film” and “layer” can optionally be interchanged each other.

“Display device” refers to a structure configured to display an image using electro-optic layers. For example, the term display device may refer to a display panel including the electro-optic layer, or it may refer to a structure in which other optical members (for example, polarizing member, backlight, touch panel, or the like) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying a liquid crystal display device including a liquid crystal layer and an organic EL display device including an organic EL layer as the display device, the structure in the present embodiment can be applied to a display device including the other electro-optic layers described above.

The expressions “α includes A, B, or C”, “α includes any of A, B, or C”, and “α includes one selected from a group consisting of A, B, and C” do not exclude the case where α includes multiple combinations of A to C unless otherwise specified. Furthermore, these expressions do not exclude the case where α includes other elements.

In addition, the following embodiments may be combined with each other as long as there is no technical contradiction.

An object of an embodiment of the present invention is to suppress variation in electrical characteristics of a semiconductor device before and after a stress test.

### 1. First Embodiment

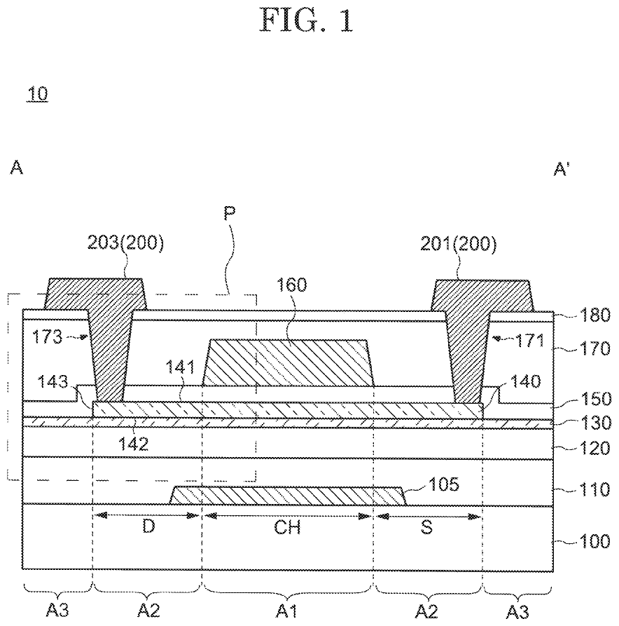

A semiconductor device according to an embodiment of the present invention will be described with reference to FIG. 1 to FIG. 16. For example, a semiconductor device of the embodiment described below may be used in an integrated circuit (IC) such as a micro-processing unit (MPU) or a memory circuit in addition to a transistor used in a display device.

### 1-1. Configuration of Semiconductor Device 10

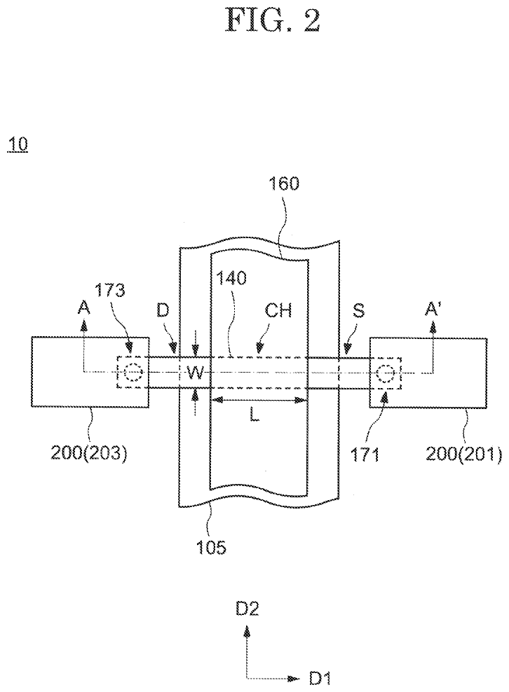

A configuration of a semiconductor device 10 according to an embodiment of the present invention will be described with reference to FIG. 1 and FIG. 2. FIG. 1 is a cross-sectional view showing an outline of a semiconductor device according to an embodiment of the present invention. FIG. 2 is a plan view showing an outline of a semiconductor device according to an embodiment of the present invention.

As shown in FIG. 1, the semiconductor device 10 is arranged above a substrate 100. The semiconductor device 10 includes a gate electrode 105, gate insulating layers 110 and 120, a metal oxide layer 130, an oxide semiconductor layer 140, a gate insulating layer 150, a gate electrode 160, insulating layers 170 and 180, a source electrode 201, and a drain electrode 203. If the source electrode 201 and the drain electrode 203 are not specifically distinguished from each other, they may be referred to as a source-drain electrode 200.

The gate electrode 105 is arranged on the substrate 100. The gate insulating layers 110 and 120 are arranged on the substrate 100 and the gate electrode 105. The metal oxide layer 130 is arranged on the gate insulating layer 120. The metal oxide layer 130 is in contact with the gate insulating layer 120. The oxide semiconductor layer 140 is arranged on the metal oxide layer 130. The oxide semiconductor layer 140 is in contact with the metal oxide layer 130. The oxide semiconductor layer 140 is patterned. Part of the metal oxide layer 130 extends outside the pattern of the oxide semiconductor layer 140 beyond the end portion of the oxide semiconductor layer 140. However, the metal oxide layer 130 may be patterned in the same planar shape as the oxide semiconductor layer 140.

The gate electrode 105 may be referred to as a “first gate electrode”. The gate insulating layers 110 and 120 and the metal oxide layer 130 may be collectively referred to as a “first insulating layer”. In this case, the gate insulating layer 110 may be referred to as a “first layer”, the gate insulating layer 120 may be referred to as a “second layer”, and the metal oxide layer 130 may be referred to as a “third layer”. As will be described in detail later, the gate insulating layer 110 is a layer containing silicon and nitrogen. The gate insulating layer 120 is a layer containing silicon and oxygen. The metal oxide layer 130 is a layer containing aluminum and oxygen.

A thickness of the gate insulating layer 110 is 10 nm or more and 190 nm or less, 10 nm or more and 150 nm or less, or 10 nm or more and 100 nm or less. A thickness of the gate insulating layer 120 is 10 nm or more and 100 nm or less, 10 nm or more and 75 nm or less, or 10 nm or more and 50 nm or less. A total thickness of the gate insulating layers 110 and 120 is 300 nm or less, 200 nm or less, or 150 nm or less. As will be described in detail later, by setting thicknesses of the gate insulating layers 110 and 120 and the metal oxide layer 130 within the ranges described above, reliability of the semiconductor device 10 in the stress test is improved.

The thickness of the metal oxide layer 130 is 1 nm or more and 10 nm or less, 1 nm or more and 4 nm or less, or 1 nm or more and 3 nm or less. A ratio of the thickness of the metal oxide layer 130 with respect to a thickness of the oxide semiconductor layer 140 is 1/30 or more and ⅔ or less, 1/30 or more and 4/30 or less, or 1/30 or more and 1/10 or less.

In other words, the gate insulating layer 120 is arranged between the substrate 100 and the metal oxide layer 130. In other words, the metal oxide layer 130 is in contact with each of the gate insulating layer 120 and the oxide semiconductor layer 140 between the gate insulating layer 120 and the oxide semiconductor layer 140. Although details will be described later, the gate insulating layer 120 is an insulating layer containing oxygen. Specifically, the gate insulating layer 120 is an insulating layer having a function of releasing oxygen by heat treatment at 600° C. or lower. Oxygen released from the gate insulating layer 120 by the heat treatment repairs oxygen vacancies formed in the oxide semiconductor layer 140.

In the present embodiment, no semiconductor layer or oxide semiconductor layer is arranged between the metal oxide layer 130 and the substrate 100.

In the present embodiment, although a configuration in which the metal oxide layer 130 is in contact with the gate insulating layer 120 and the oxide semiconductor layer 140 is in contact with the metal oxide layer 130 is exemplified, the configuration is not limited to this configuration. Another layer may be arranged between the gate insulating layer 120 and the metal oxide layer 130. Another layer may be arranged between the metal oxide layer 130 and the oxide semiconductor layer 140.

The gate electrode 160 faces the oxide semiconductor layer 140. The gate insulating layer 150 is arranged between the oxide semiconductor layer 140 and the gate electrode 160. The gate insulating layer 150 is in contact with the oxide semiconductor layer 140. A surface of main surfaces of the oxide semiconductor layer 140 that is in contact with the gate insulating layer 150 is referred to as an upper surface 141. A surface of the main surfaces of the oxide semiconductor layer 140 that is in contact with the metal oxide layer 130 is referred to as an lower surface 142. A surface between the upper surface 141 and the lower surface 142 is referred to as a side surface 143. The insulating layers 170 and 180 are arranged above the gate insulating layer 150 and the gate electrode 160. Openings 171 and 173 that reach the oxide semiconductor layer 140 are arranged in the insulating layers 170 and 180. The source electrode 201 is arranged inside the opening 171. The source electrode 201 is in contact with the oxide semiconductor layer 140 at the bottom of the opening 171. The drain electrode 203 is arranged inside the opening 173. The drain electrode 203 is in contact with the oxide semiconductor layer 140 at the bottom of the opening 173.

The gate electrode 160 may be referred to as a “second gate electrode”. The gate insulating layer 150 may be referred to as a “second insulating layer”.

The gate electrode 105 has a function as a bottom-gate of the semiconductor device 10 and a function as a light-shielding film for the oxide semiconductor layer 140. The gate insulating layer 110 has a function as a barrier film for shielding impurities that diffuse from the substrate 100 toward the oxide semiconductor layer 140. The gate insulating layers 110 and 120 have a function as a gate insulating layer for the bottom-gate. The metal oxide layer 130 is a layer containing a metal oxide containing aluminum as the main component, and has a function as a gas barrier property film for shielding a gas such as oxygen and hydrogen. Furthermore, the metal oxide layer 130 has a function of suppressing that holes move from the oxide semiconductor layer 140 to the gate insulating layer 120 in a stress tests.

The semiconductor device 10 is divided into a first region A1, a second region A2, and a third region A3 based on the patterns of the gate electrode 160 and the oxide semiconductor layer 140. The first region A1 is a region that overlaps the gate electrode 160 in a plan view. The second region A2 is a region that does not overlap the gate electrode 160 but overlaps the oxide semiconductor layer 140 in a plan view. The third region A3 is a region that does not overlap both the gate electrode 160 and the oxide semiconductor layer 140 in a plan view.

Although a configuration that a thickness of the gate insulating layer 150 in the second region A2 and the third region A3 is the same as a thickness of the gate insulating layer 150 in the first region A1, the configuration is not limited to this configuration. For example, the thickness of the gate insulating layer 150 in the second region A2 and the third region A3 may be smaller than the thickness of the gate insulating layer 150 in the first region A1. In other words, the thickness of the gate insulating layer 150 in the region not overlapping the gate electrode 160 in a plan view may be smaller than the thickness of the gate insulating layer 150 in the region overlapping the gate electrode 160.

The oxide semiconductor layer 140 is divided into a source region S, a drain region D, and a channel region CH based on the pattern of the gate electrode 160. The source region S and the drain region D are regions corresponding to the second region A2. The channel region CH is a region corresponding to the first region A1. In a plan view, an end portion in the channel region CH is consistent with an end portion of the gate electrode 160. The oxide semiconductor layer 140 in the channel region CH have semiconductor properties. Each of the oxide semiconductor layer 140 in the source region S and the drain region D has conductive properties. That is, carrier concentrations of the oxide semiconductor layer 140 in the source region S and the drain region D are higher than a carrier concentration of the oxide semiconductor layer 140 in the channel region CH. The source electrode 201 and the drain electrode 203 contacts the oxide semiconductor layer 140 in the source region S and the drain region D, respectively, and are electrically connected to the oxide semiconductor layer 140. The oxide semiconductor layer 140 may be a single-layer structure or a stacked structure.

The gate electrode 160 has a function as a top-gate of the semiconductor device 10 and a light-shielding film for the oxide semiconductor layer 140. The gate insulating layer 150 has a function as a gate insulating layer for the top-gate. The gate insulating layer 150 may has a function of releasing oxygen by a heat treatment in a manufacturing process similar to the gate insulating layer 120. The insulating layers 170 and 180 insulate the gate electrode 160 and the source-drain electrode 200 and have a function of reducing parasitic capacitance therebetween. Operations of the semiconductor device 10 are controlled mainly by a voltage supplied to the gate electrode 160. An auxiliary voltage is supplied to the gate electrode 105. However, in the case of using the gate electrode 105 simply as a light-shielding film, a specific voltage is not supplied to the gate electrode 105, and a potential of the gate electrode 105 may be in a floating. That is, the gate electrode 105 may simply be referred to as a “light-shielding film.” In the case mentioned above, the shielding film may be an insulator.

In the present embodiment, although a configuration using a dual-gate transistor in which the gate electrode is arranged both above and below the oxide semiconductor layer as the semiconductor device 10 is exemplified, the configuration is not limited to this configuration. For example, a bottom-gate transistor in which the gate electrode is arranged only below the oxide semiconductor layer or a top-gate transistor in which the gate electrode is arranged only above the oxide semiconductor layer may be used as the semiconductor device 10. The above configuration is merely an embodiment, and the present invention is not limited to the above configuration.

Referring to FIG. 1 and FIG. 2, the lower surface 142 of the oxide semiconductor layer 140 is covered with the metal oxide layer 130. In particular, in the present embodiment, all of the lower surface 142 of the oxide semiconductor layer 140 is covered with the metal oxide layer 130. In a direction D1 shown in FIG. 2, a width of the gate electrode 105 is greater than a width of the gate electrode 160. The direction D1 is a direction connecting the source electrode 201 and the drain electrode 203, and is a direction indicating a channel length L of the semiconductor device 10. Specifically, a length in the direction D1 in the region (the channel region CH) where the oxide semiconductor layer 140 and the gate electrode 160 overlap is the channel length L, and a width in a direction D2 in the channel region CH is a channel width W.

In the present embodiment, although a configuration in which all of the lower surface 142 of the oxide semiconductor layer 140 is covered with the metal oxide layer 130 is exemplified, the present invention is not limited to this configuration. For example, part of the lower surface 142 of the oxide semiconductor layer 140 may not be in contact with the metal oxide layer 130. For example, all of the lower surface 142 of the oxide semiconductor layer 140 in the channel region CH may be covered with the metal oxide layer 130, and all or part of the lower surface 142 of the oxide semiconductor layer 140 in the source region S and the drain region D may not be covered with the metal oxide layer 130. That is, all or part of the lower surface 142 of the oxide semiconductor layer 140 in the source region S and the drain region D may not be in contact with the metal oxide layer 130. However, in the above configuration, part of the lower surface 142 of the oxide semiconductor layer 140 in the channel region CH may not be covered with the metal oxide layer 130, and the other part of the lower surface 142 may be in contact with the metal oxide layer 130.

In the present embodiment, although a configuration in which the gate insulating layer 150 is formed on the entire surface and the openings 171 and 173 are arranged in the gate insulating layer 150 is exemplified, the configuration is not limited to this configuration. The gate insulating layer 150 may be patterned in a shape that is different from the shape in which the openings 171 and 173 are arranged. For example, the gate insulating layer 150 may be patterned to expose all or part of the oxide semiconductor layer 140 in the source region S and the drain region D. That is, the gate insulating layer 150 in the source region S and the drain region D may be removed, and the oxide semiconductor layer 140 and the insulating layer 170 may be in contact with each other in these regions.

In FIG. 2, although a configuration in which the source-drain electrode 200 does not overlap the gate electrode 105 and the gate electrode 160 in a plan view is exemplified, the configuration is not limited to this configuration. For example, in a plan view, the source-drain electrode 200 may overlap at least one of the gate electrode 105 and the gate electrode 160. The above configuration is merely an embodiment, and the present invention is not limited to the above configuration.

### 1-2. Material of Each Member of Semiconductor Device 10

A rigid substrate having translucency, such as a glass substrate, a quartz substrate, a sapphire substrate, or the like, is used as the substrate 100. In the case where the substrate 100 needs to have flexibility, a substrate containing a resin such as a polyimide substrate, an acryl substrate, a siloxane substrate, or a fluororesin substrate is used as the substrate 100. In the case where the substrate containing a resin is used as the substrate 100, impurities may be introduced into the resin in order to improve the heat resistance of the substrate 100. In particular, in the case where the semiconductor device 10 is a top-emission display, since the substrate 100 does not need to be transparent, impurities that deteriorate the translucency of the substrate 100 may be used. In the case where the semiconductor device 10 is used for an integrated circuit that is not a display device, a substrate without translucency such as a semiconductor substrate such as a silicon substrate, a silicon carbide substrate, a compound semiconductor substrate, or a conductive substrate such as a stainless substrate is used as the substrate 100.

Common metal materials are used for the light-shielding layer 105, the gate electrode 160, and the source-drain electrode 200. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof are used as these members. The materials described above may be used in a single layer or a stacked layer as the light-shielding layer 105, the gate electrode 160, and the source-drain electrode 200. A material other than the metal materials described above may be used as a light-shielding layer instead of the gate insulating layer 105 if conductivity is not required. For example, a black matrix such as a black resin may be used as the light-shielding layer. The light-shielding layer 105 may be a single-layer structure or a stacked structure. For example, the light-shielding layer 105 may be a stacked structure of a red color filter, a green color filter, and a blue color filter.

Common insulating materials are used as the gate insulating layer 110, 120, and the insulating layers 170 and 180. For example, inorganic insulating layers such as silicon oxide (SiOₓ), silicon oxynitride (SiOₓN_{y}), aluminum oxide (AlOₓ), and aluminum oxynitride (AlOₓN_{y}) are used as the gate insulating layer 120 and the insulating layer 180. Inorganic insulating layers such as silicon nitride (SiNₓ), silicon nitride oxide (SiNₓO_{y}), aluminum nitride (AlNₓ), and aluminum nitride oxide (AlNₓO_{y}) are used as the gate insulating layer 110 and the insulating layer 170. However, an inorganic insulating layer such as silicon oxide (SiOₓ), silicon oxynitride (SiOₓN_{y}), aluminum oxide (AlOₓ), or aluminum oxynitride (AlOₓN_{y}) may be used as the insulating layer 170. An inorganic insulating layer such as silicon nitride (SiNₓ), silicon nitride oxide (SiNₓO_{y}), aluminum nitride (AlNₓ), and aluminum nitride oxide (AlNₓO_{y}) may be used as the insulating layer 180.

Among the insulating layers described above, the insulating layer containing oxygen is used as the gate insulating layer 150. For example, an inorganic insulating layer such as silicon oxide (SiOₓ), silicon oxynitride (SiOₓN_{y}), aluminum oxide (AlOₓ), and aluminum oxynitride (AlOₓN_{y}) are used as the gate insulating layer 150.

An insulating layer having a function of releasing oxygen by heat treatment is used as the gate insulating layer 120. That is, an oxide insulating layer containing excess oxygen is used as the gate insulating layer 120. For example, a temperature of heat treatment at which the gate insulating layer 120 releases oxygen is 600° C. or less, 500° C. or less, 450° C. or less, or 400° C. or less. That is, for example, the gate insulating layer 120 releases oxygen at a heat treatment temperature performed in a manufacturing process of the semiconductor device 10 in the case where a glass substrate is used as the substrate 100. Similar to the gate insulating layer 120, an insulating layer having a function of releasing oxygen by heat treatment may be used for at least one of the insulating layers 170 and 180.

An insulating layer with few defects is used as the gate insulating layer 150. For example, in the case where a composition ratio of oxygen in the gate insulating layer 150 is compared with a composition ratio of oxygen in an insulating layer (hereinafter referred to as “other insulating layer”) having a composition similar to that of the gate insulating layer 150, the composition ratio of oxygen in the gate insulating layer 150 is closer to the stoichiometric ratio with respect to the insulating layer than the composition ratio of oxygen in that other insulating layer. Specifically, in the case where silicon oxide (SiOₓ) is used for each of the gate insulating layer 150 and the insulating layer 180, the composition ratio of oxygen in the silicon oxide used as the gate insulating layer 150 is close to the stoichiometric ratio of silicon oxide as compared with the composition ratio of oxygen in the silicon oxide used as the insulating layer 180. For example, a layer in which no defects are observed when evaluated by the electron-spin resonance (ESR) may be used as the gate insulating layer 150.

SiOₓN_{y}and AlOₓN_{y} described above are a silicon compound and an aluminum compound containing nitrogen (N) in a ratio (x>y) smaller than that of oxygen (O). SiNₓO_{y}and AlNₓO_{y} are a silicon compound and an aluminum compound containing oxygen in a ratio (x>y) smaller than that of nitrogen.

A metal oxide containing aluminum as the main component is used as the metal oxide layer 130. For example, an inorganic insulating layer such as aluminum oxide (AlOₓ), aluminum oxynitride (AlOₓN_{y}), aluminum nitride oxide (AlNₓO_{y}), or aluminum nitride (AlNₓ) is used as the metal oxide layer 130. The “metal oxide layer 130 containing aluminum as the main component” means that the ratio of aluminum contained in the metal oxide layer 130 is 1% or more of the total amount of the metal oxide layer 130. The ratio of aluminum contained in the metal oxide layer 130 may be 5% or more and 70% or less, 10% or more and 60% or less, or 30% or more and 50% or less of the total amount of the metal oxide layer 130. The above ratio may be a mass ratio or a weight ratio.

A metal oxide having semiconductor properties may be used as the oxide semiconductor layer 140. For example, an oxide semiconductor containing indium (In), gallium (Ga), zinc (Zn), and oxygen (O) may be used as the oxide semiconductor layer 140. For example, an oxide semiconductor having a composition ratio of In:Ga:Zn:O=1:1:1:4 may be used as the oxide semiconductor layer 140. However, the oxide semiconductor containing In, Ga, Zn and O used in the present embodiment is not limited to the above-described composition. An oxide semiconductor having a composition other than the above may be used as the oxide semiconductor. For example, an oxide semiconductor layer having a higher ratio of In than those described above may be used to improve mobility. On the other hand, in order to increase the bandgap and reduce the effect of photoirradiation, an oxide semiconductor layer having a larger ratio of Ga than those described above may be used.

For example, an oxide semiconductor containing two or more metals including indium (In) may be used as the oxide semiconductor layer 140 in which the ratio of In is larger than that described above. In this case, the ratio of indium with respect to the entire the oxide semiconductor layer 140 may be 50% or more. Gallium (Ga), zinc (Zn), aluminum (Al), hafnium (Hf), yttrium (Y), zirconia (Zr), and lanthanoids may be used as the oxide semiconductor layer 140 in addition to indium. Elements other than those described above may be used as the oxide semiconductor layer 140.

Other elements may be added to the oxide semiconductor containing In, Ga, Zn, and O as the oxide semiconductor layer 140, and metal elements such as Al, Sn may be added. In addition to the above oxide semiconductor, an oxide semiconductor (IGO) containing In, Ga, an oxide semiconductor (IZO) containing In, Zn, an oxide semiconductor (ITZO) containing In, Sn, Zn, an oxide semiconductor containing In, W may be used as the oxide semiconductor layer 140.

In the case where the ratio of the indium element is large, the oxide semiconductor layer 140 is likely to crystallize. As described above, in the oxide semiconductor layer 140, the oxide semiconductor layer 140 having a polycrystalline structure can be obtained by using a material in which the ratio of the indium element with respect to the total metal element is 50% or more. The oxide semiconductor layer 140 preferably contains gallium as a metal element other than indium. Gallium belongs to the same Group 13 element as indium. Therefore, the crystallinity of the oxide semiconductor layer 140 is not inhibited by gallium, and the oxide semiconductor layer 140 has a polycrystalline structure.

Although a detailed method of manufacturing the oxide semiconductor layer 140 will be described later, the oxide semiconductor layer 140 can be formed using a sputtering method. A composition of the oxide semiconductor layer 140 formed by the sputtering method depends on a composition of a sputtering target. Even though the oxide semiconductor layer 140 has a polycrystalline structure, the composition of the sputtering target is substantially consistent with the composition of the oxide semiconductor layer 140. In this case, the composition of the metal element of the oxide semiconductor layer 140 can be specified based on the composition of the metal element of the sputtering target.

In the case where the oxide semiconductor layer 140 has a polycrystalline structure, a composition of the oxide semiconductor layer may be specified using X-ray diffraction (X-ray Diffraction: XRD). Specifically, a composition of the metal element of the oxide semiconductor layer can be specified based on the crystalline structure and the lattice constant of the oxide semiconductor layer obtained by the XRD method. Furthermore, the composition of the metal element of the oxide semiconductor layer 140 can also be identified using fluorescent X-ray analysis, Electron Probe Micro Analyzer (EPMA) analysis, or the like. However, the oxygen element contained in the oxide semiconductor layer 140 may not be specified by these methods because the oxygen element varies depending on the sputtering process conditions.

As described above, the oxide semiconductor layer 140 may have an amorphous structure or a polycrystalline structure. The oxide semiconductor having a polycrystalline structure can be manufactured using a Poly-OS (Poly-crystalline Oxide Semiconductor) technique. In the following, the oxide semiconductor having the polycrystalline structure may be described as the Poly-OS when distinguished from the oxide semiconductor having the amorphous structure.

### 1-3. Electrical Characteristics of Semiconductor Device 10

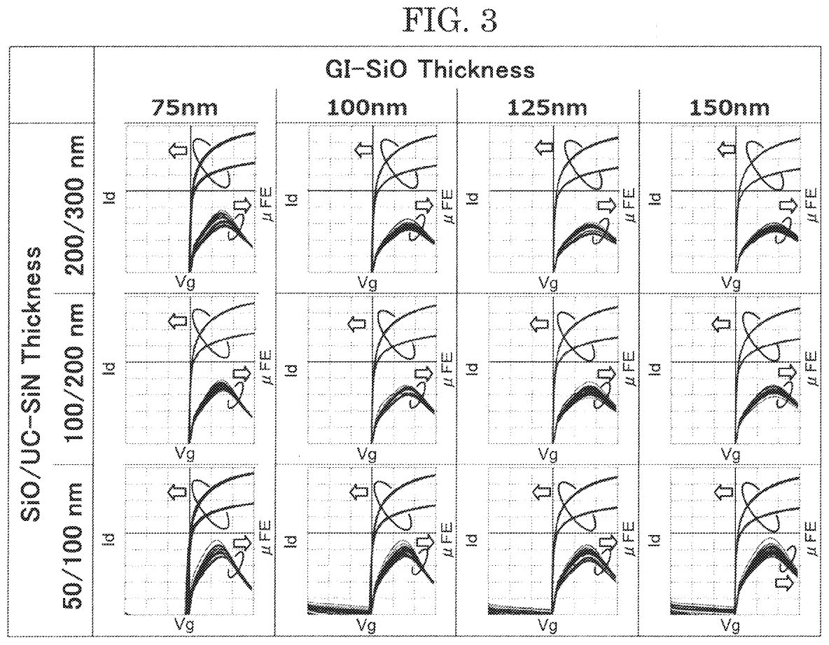

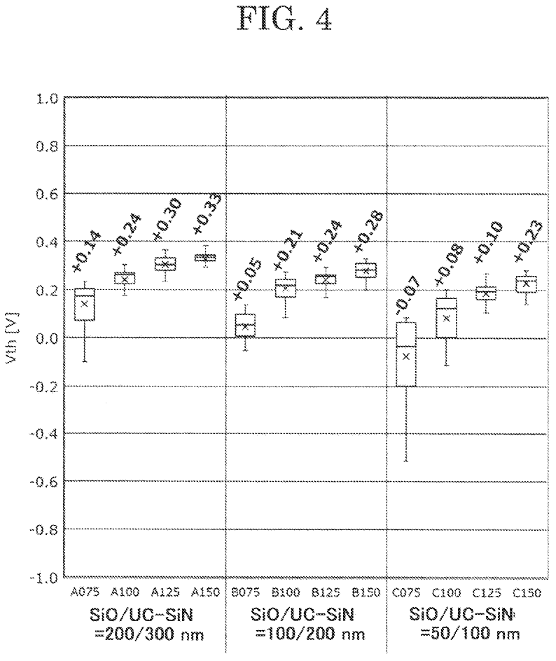

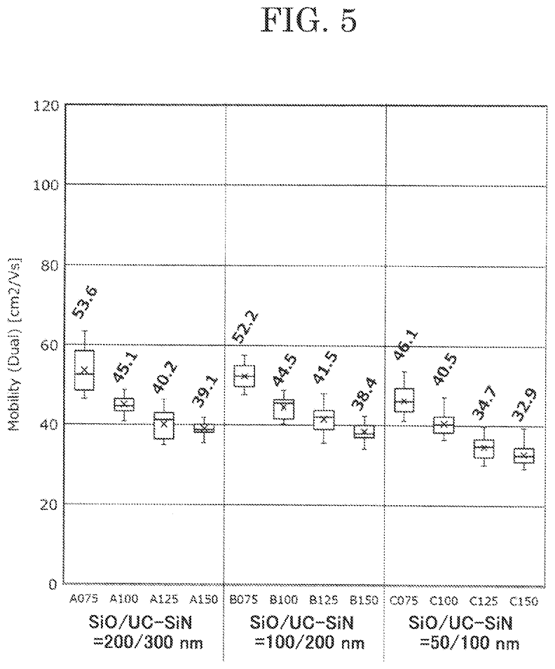

Electrical characteristics of the semiconductor device 10 will be described with reference to FIG. 3 to FIG. 5. FIG. 3 is a diagram showing electrical characteristics of a semiconductor device according to an embodiment of the present invention. FIG. 4 is a diagram showing a threshold voltage calculated from electrical characteristics of a semiconductor device according to an embodiment of the present invention. FIG. 5 is a diagram showing mobility calculated from electrical characteristics of a semiconductor device according to an embodiment of the present invention. In FIG. 3 to FIG. 5, electrical characteristics of a plurality of semiconductor devices 10 having different thicknesses of the gate insulating layers 110, 120, and 150 are shown. A structure of the semiconductor device 10 showing the electrical characteristics of FIG. 3 to FIG. 5 is the same as the structure of the semiconductor device 10 shown in FIG. 1. In any conditions, an amount of impurities to be implanted into the oxide semiconductor layer 140 is adjusted so that resistance values of the oxide semiconductor layers 140 in the source region S and the drain region D are substantially the same.

In the semiconductor device 10, a silicon nitride film is used as the gate insulating layer 110, a silicon oxide film is used as the gate insulating layer 120, and a silicon oxide film is used as the gate insulating layer 150. The gate insulating layer 110 is denoted as “UC-SiN”. The gate insulating layer 120 is denoted as “SiO”. The gate insulating layer 150 is denoted as “GI-SiO”. Aluminum oxide is used as the metal oxide layer 130.

The thicknesses of the gate insulating layers 110 and 120 (SiO/UC-SiN Thickness) are 50 nm/100 nm, 100 nm/200 nm, or 200 nm/300 nm. The film thickness of the gate insulating layer 150 (GI-SiO Thickness) with respect to each of film thickness of the SiO/UC-SiN is 75 nm, 100 nm, 125 nm, or 150 nm.

Measurement conditions of the electrical characteristics shown in FIG. 3 are as follows.
Size of channel region CH: W/L=4.5 μm/3.0 μm
Source/Drain Voltage: 0.1 V, 10 V
Gate voltage: −15 V to +15 V
Measurement environment: room temperature, dark room
Number of measurement points: 26

The horizontal line of the solid line shown in FIG. 3 is shown at the position of the scale where drain current Id is 10⁻⁷ [A] and mobility μFE is 100 [cm²/Vs]. The drain current changes by one digit per scale (per horizontal dotted line). The mobility varies by 20 [cm²/Vs] per scale. The vertical line of the solid line shown in FIG. 3 is shown at the position of the scale where the gate voltage Vg is 0 [V]. The value of the gate voltage changes by 5 [V] per scale (per vertical dotted line). In FIG. 3, the electric properties indicated by the leftward arrows indicate Id-Vg properties of the device 10. There are two types of Id-Vg properties displayed. Of the two types of Id-Vg properties, Id-Vg properties in which currents are relatively large are properties in the case where the source drain voltage is 10 V, and Id-Vg properties in which currents are relatively small are properties in the case where the source drain voltage is 0.1 V. In each graph of FIG. 3, the electric characteristics indicated by the rightward arrow indicates the mobility of the semiconductor device 10. As shown in FIG. 3, good electric properties with no particular anomaly are obtained under most conditions, and the mobility is 50 [cm²/Vs] or more.

FIG. 4 is a box-and-whisker plot of the threshold voltage calculated from the electrical characteristics of FIG. 3. In FIG. 4, a maximum value (upper edge of the whisker), a minimum value (lower edge of the whisker), a distribution of the median 50% of the data (from the upper edge to the lower edge of the box), an average value (x mark), and a median value (boundary between the upper box and the lower box) in each calculated value are shown. As shown in FIG. 4, in each of film thicknesses of the SiO/UC-SiN, a threshold voltage Vth is shifted in a negative direction as the film thickness (GI-SiO) of the gate insulating layer 150 is smaller. In the case where the thickness (GI-SiO) of the gate insulating layer 150 is compared under the same condition, the threshold voltage Vth is shifted in the negative direction as film thickness of SiO/UC-SiN is smaller.

FIG. 5 is a box-and-whisker plot of the mobility calculated from the electrical characteristics of FIG. 3. As shown in FIG. 5, the mobility is larger as the thickness (GI-SiO) of the gate insulating layer 150, film thicknesses are smaller in each of the SiO/UC-SiN. In the case where the thickness (GI-SiO) of the gate insulating layer 150 is compared under the same conditions, although the mobility tends to be smaller as film thickness of the SiO/UC-SiN is smaller, the mobility does not decrease greatly, and good properties are obtained under any conditions.

### 1-4. Reliability of Semiconductor Device 10

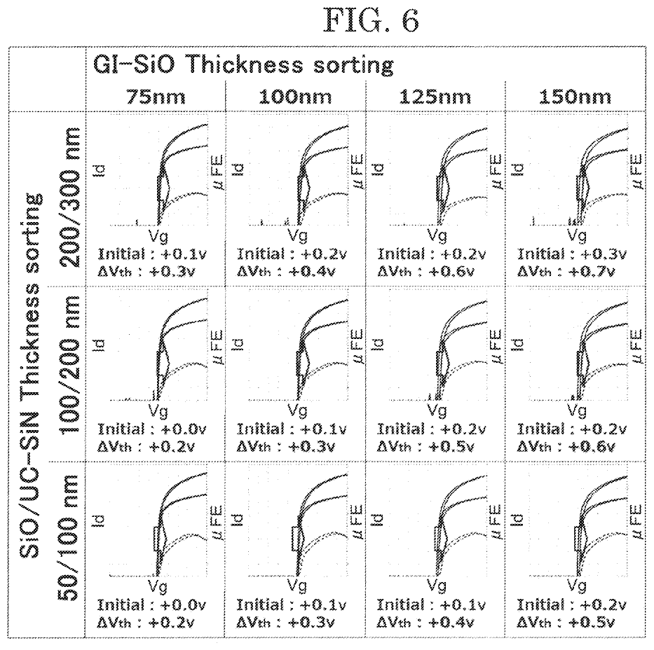

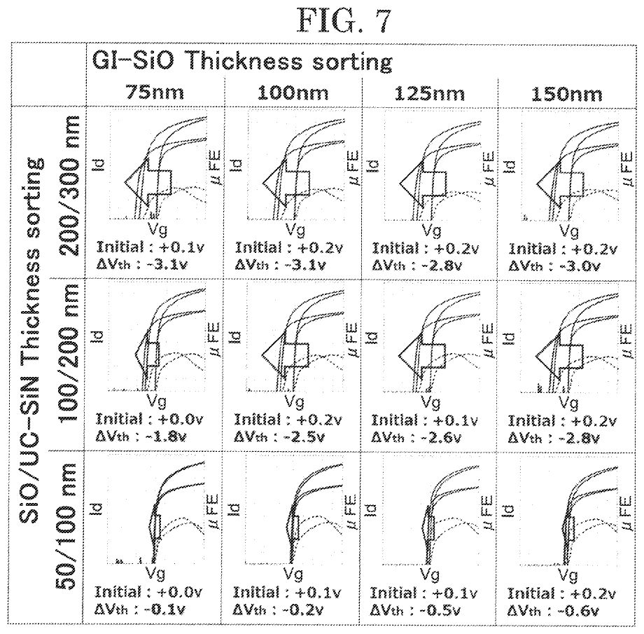

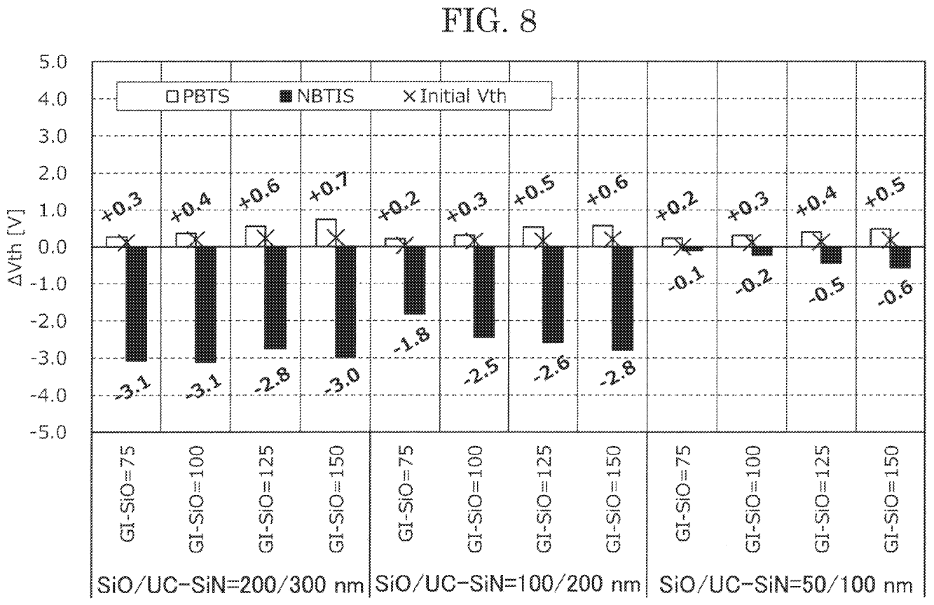

The reliability of the semiconductor device 10 will be described with reference to FIG. 6 to FIG. 8. FIG. 6 and FIG. 7 are diagrams showing electrical characteristics before and after the stress test of a semiconductor device according to an embodiment of the present invention. FIG. 8 is a diagram showing a variation in a threshold voltage calculated from electrical characteristics before and after the stress test of a semiconductor device according to an embodiment of the present invention. FIG. 6 to FIG. 8 show results of a reliability test for the semiconductor device 10 shown in FIG. 3 to FIG. 5.

FIG. 6 shows the results of the reliability test according to Positive Bias Temperature Stress (PBTS). FIG. 7 shows the results of the reliability test according to Negative Bias Temperature Illumination Stress (NBTIS). FIG. 8 shows the result of the reliability test calculated based on the electrical characteristics of the semiconductor device 10 shown in FIG. 6 and FIG. 7.

Conditions for the PBTS test are as follows.
Size of channel region CH: W/L=4.5 μm/3.0 μm
Light irradiation condition: No irradiation (dark room)
Gate voltage: +30 V
Source/Drain Voltage: 0 V
Stress application duration: 1000 sec
Stage temperature when stress is applied: 85° C.

Conditions for the NBTIS test are as follows.
Size of channel region CH: W/L=4.5 μm/3.0 μm
Light irradiation condition: Irradiation present (7000 lux)
Gate voltage: −20 V
Source/Drain Voltage: 0 V
Stress application duration: 1000 sec
Stage temperature when stress is applied: 85° C.

In FIG. 8, the results of the PBTS test are shown in a white bar graph. The NBTIS test is shown in a black bar graph. Threshold voltages Vth of pre-tests are marked with x.

As shown in FIG. 6 and FIG. 8, the threshold voltage Vth is positively shifted before and after the PBTS test. The smaller the film thickness (GI-SiO) of the gate insulating layer 150, the smaller an amount of a positive shift. In the case where the thickness (GI-SiO) of the gate insulating layer 150 is the same, the smaller the SiO/UC-SiN film thickness, the smaller the amount of the positive shift.

As shown in FIG. 7 and FIG. 8, the threshold voltage Vth is negatively shifted before and after the NBTIS test. In the condition where film thickness of the SiO/UC-SiN is 200 nm/300 nm, an amount of this negative shift does not depend on film thickness of the GI-SiO. On the other hand, in the condition where film thickness of the SiO/UC-SiN is 100 nm/200 nm, the smaller film thickness of the GI-SiO, the smaller the negative shift amount. In particular, the negative shift amount in the condition where film thickness of the GI-SiO is 75 nm is significantly reduced compared to the negative shift amount in the condition where film thickness of the GI-SiO is 100 nm. Furthermore, the negative shift amount in the condition where film thickness of the SiO/UC-SiN is 50 nm/100 nm is dramatically reduced compared to the negative shift amount in the condition described above. Among the conditions where film thickness of the SiO/UC-SiN is 50 nm/100 nm, the smaller film thickness of the GI-SiO, the smaller the negative shift.

According to the present embodiment, the thickness of the gate insulating layer 110 containing silicon and nitrogen is 10 nm or more and 190 nm or less, the thickness of the gate insulating layer 120 containing silicon and oxygen is 10 nm or more and 100 nm or less, the total thickness of the gate insulating layers 110 and 120 is 200 nm or less, and the thickness of the metal oxide layer 130 containing aluminum and oxygen is 1 nm or more and 10 nm or less, and thus, dramatic improvement has been confirmed particularly in the NBTIS test.

In the NBTIS test, −20 V gate voltage is applied to the gate electrodes 105 and 160 as described above. Therefore, holes generated in the oxide semiconductor layer 140 by the light irradiation are attracted to either of the gate electrodes 105 and 160. Here, in the case where the thicknesses of the gate insulating layers 110 and 120 are small, an influence of an electric field generated by the gate electrode 105 on the oxide semiconductor layer 140 is relatively strong. As a result, it is considered that most of the holes generated in the oxide semiconductor layer 140 are attracted to the gate electrode 105. In a conventional transistor, a hole is trapped by a gate insulating layer in a bottom-gate side, which causes a negative shift in a threshold voltage of a transistor characteristic in the NBTIS test. On the other hand, in the present embodiment, since the metal oxide layer 130 is arranged below the oxide semiconductor layer 140, it is difficult for the holes generated in the oxide semiconductor layer 140 to reach the gate insulating layer 120, and it is considered that an amount of holes trapped in the gate insulating layer 120 is reduced.

### 1-5. Method for Manufacturing Semiconductor Device 10

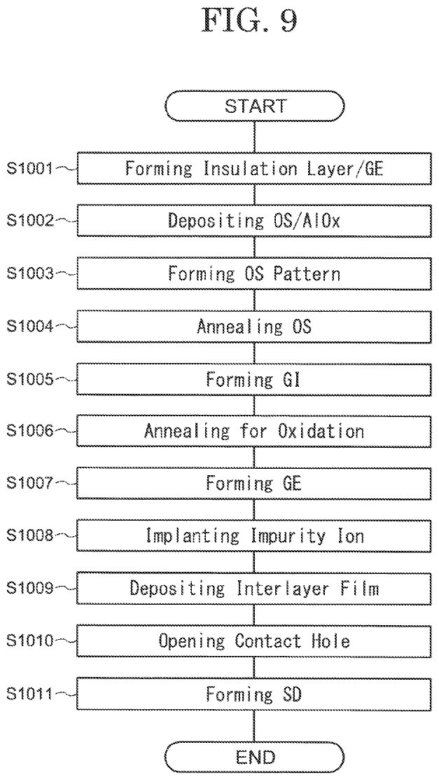

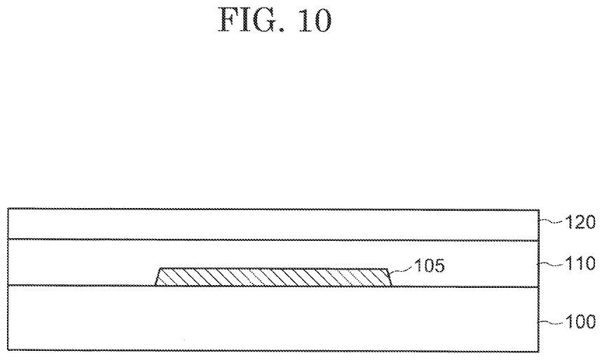

A method for manufacturing a semiconductor device 10 according to an embodiment of the present invention will be described with reference to FIG. 9 to FIG. 17. FIG. 9 is a sequence diagram showing a method for manufacturing a semiconductor device according to an embodiment of the present invention. FIG. 10 to FIG. 17 are cross-sectional views showing a method for manufacturing a semiconductor device according to an embodiment of the present invention.

As shown in FIG. 9 and FIG. 10, the gate electrode 105 is formed on the substrate 100, and the gate insulating layer 110, 120 are formed on the gate electrode 105 (“Forming Insulation Layer/GE” in step S1001 of FIG. 9). For example, silicon nitride is formed as the gate insulating layer 110. For example, silicon oxide is formed as the gate insulating layer 120. The gate insulating layers 110 and the gate insulating layer 120 are deposited by a CVD (Chemical Vapor Deposition) method.

Using silicon nitride as the gate insulating layer 110 allows the gate insulating layer 110 to block impurities that diffuse, for example, from the substrate 100 toward the oxide semiconductor layer 140. The silicon oxide used as the gate insulating layer 120 is silicon oxide having a physical property of releasing oxygen by heat treatment.

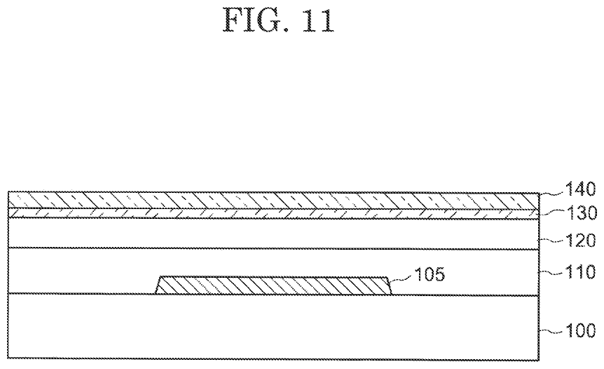

As shown in FIG. 9 and FIG. 11, the metal oxide layer 130 and the oxide semiconductor layer 140 is formed on the gate insulating layer 120 (“Depositing OS/AlOx” in step S1002 of FIG. 9). The metal oxide layer 130 and the gate insulating layer 140 is formed above the substrate 100. The oxide semiconductor layer 140 is deposited by a sputtering method or an atomic layer deposition method (ALD).

For example, the thickness of the oxide semiconductor layer 140 is 10 nm or more and 100 nm or less, 15 nm or more and 70 nm or less, or 15 nm or more and 40 nm or less. In the present embodiment, the thickness of the oxide semiconductor layer 140 is 15 nm. The oxide semiconductor layer 140 before the heat treatment (OS anneal) described later is amorphous.

In the case where the oxide semiconductor layer 140 is crystallized by the OS anneal described later, the oxide semiconductor layer 140 after the deposition and before the OS anneal is preferably in an amorphous state (a state of low crystalline components of the oxide semiconductor are fewer). That is, deposition conditions of the oxide semiconductor layer 140 are preferred to be a condition such that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where temperature of the object to be deposited (the substrate 100 and structures formed thereon) is controlled.

In the case where the deposition is performed on the object to be deposited by the sputtering method, ions generated in the plasma and atoms recoiled by a sputtering target collide with the object to be deposited. Therefore, the temperature of the object to be deposited rises with the deposition process. When the temperature of the object to be deposited rises during the deposition process, microcrystals are occurred in the oxide semiconductor layer 140 immediately after the deposition process. There is a possibility that the microcrystals inhibit crystallization by subsequent OS anneal. For example, in order to control the temperature of the object to be deposited as described above, deposition may be performed while cooling the object to be deposited. For example, the object to be deposited may be cooled from a surface opposite to a deposited surface so that the temperature of the deposited surface of the object to be deposited (hereinafter, referred to as “deposition temperature”) is 100° C. or less, 70° C. or less, 50° C. or less, or 30° C. or less. As described above, depositing the oxide semiconductor layer 140 while cooling the object to be deposited makes it possible to deposit the oxide semiconductor layer 140 with few crystalline components in a state immediately after the deposition. An oxygen partial pressure in the deposition conditions of the oxide semiconductor layer 140 is 2% or more and 20% or less, 3% or more and 15% or less, or 3% or more and 10% or less.

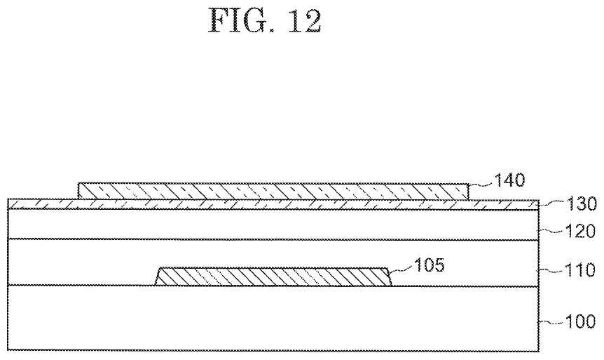

As shown in FIG. 9 and FIG. 12, a pattern of the oxide semiconductor layer 140 is formed (“Forming OS Pattern” in step S1003 of FIG. 9). Although not shown, a resist mask is formed on the oxide semiconductor layer 140, and the oxide semiconductor layer 140 is etched using the resist mask. Wet etching may be used, or dry etching may be used as the etching of the oxide semiconductor layer 140. The wet etching may include etching using an acidic etchant. For example, oxalic acid, PAN, sulfuric acid, hydrogen peroxide or hydrofluoric acid may be used as the etchant. Since the oxide semiconductor layer 140 in the step S1003 is amorphous, the oxide semiconductor layer 140 can be easily patterned into a predetermined shape by wet etching.

The pattern of the oxide semiconductor layer 140 is formed, and then heat treatment (OS anneal) is performed on the oxide semiconductor layer 140 (“Annealing OS” in step S1004 of FIG. 9). In the OS anneal, the oxide semiconductor layer 140 is held at a predetermined reaching temperature for a predetermined time. The predetermined reaching temperature is 300° C. or more and 500° C. or less, or 350° C. or more and 450° C. or less. Holding time at the reaching temperature is 15 minutes or more and 120 minutes or less, or 30 minutes or more and 60 minutes or less. In the present embodiment, the oxide semiconductor layer 140 is crystallized by the OS anneal. However, the oxide semiconductor layer 140 does not necessarily have to be crystallized by the OS anneal.

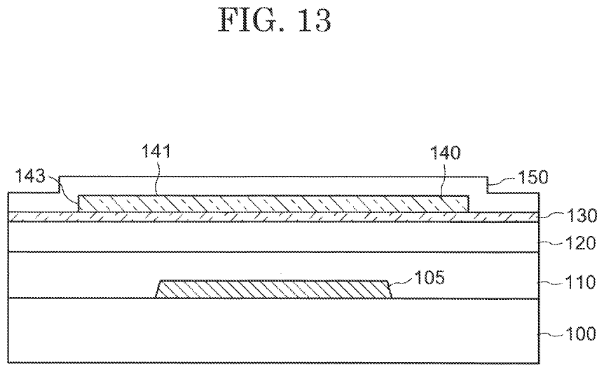

As shown in FIG. 9 and FIG. 13, the gate insulating layer 150 is deposited on the oxide semiconductor layer 140 (“Forming GI” in step S1005 of FIG. 5). For example, silicon oxide is formed as the gate insulating layer 150. The gate insulating layer 150 is formed by the CVD method. For example, the gate insulating layer 150 may be deposited at a deposition temperature of 350° C. or higher in order to form an insulating layer having few defects as described above as the gate insulating layer 150. For example, a thickness of the gate insulating layer 150 is 75 nm or more and 150 nm or less. A process of implanting oxygen may be performed on an upper part of the gate insulating layer 150 after the gate insulating layer 150 is deposited. As the process of implanting oxygen, a metal oxide layer may be formed on the gate insulating layer 150 by sputtering.

Heat treatment (oxidation anneal) for supplying oxygen to the oxide semiconductor layer 140 is performed in a state where the gate insulating layer 150 is deposited on the oxide semiconductor layer 140 (“Annealing for Oxidation” in step S1006 of FIG. 9). In the process from the deposition of the oxide semiconductor layer 140 to the deposition of the gate insulating layer 150 on the oxide semiconductor layer 140, a large amount of oxygen vacancies occurs in the upper surface 141 and the side surface 143 of the oxide semiconductor layer 140. Oxygen released from the gate insulating layers 120 and 150 are supplied to the oxide semiconductor layer 140 by the oxidation anneal described above, and the oxygen vacancies are repaired. In the case where the process of implanting oxygen into the gate insulating layer 150 is not performed, the oxidation anneal may be performed in a state in which an insulating layer that releases oxygen is formed on the gate insulating layer 150 by heat treatment.

In order to increase the amount of oxygen supplied from the gate insulating layer 150 to the oxide semiconductor layer 140, a metal oxide layer containing aluminum as the main component may be formed on the gate insulating layer 150 by the sputtering method, and then oxidation annealing may be performed in that state. The use of aluminum oxide, which has a high barrier property, as the metal oxide layer makes it possible to suppress the oxygen implanted into the gate insulating layer 150 at the time of oxidation annealing from being diffused outward. Oxygen implanted into the gate insulating layer 150 is efficiently supplied to the oxide semiconductor layer 140 by forming the metal oxide layer and the oxidation annealing.

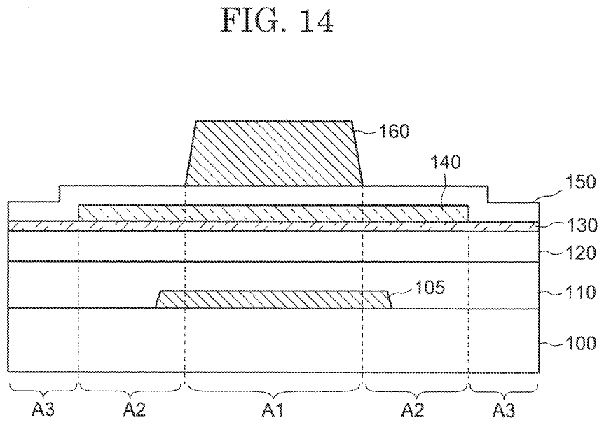

As shown in FIG. 9 and FIG. 14, the gate electrode 160 is formed (“Forming GE” in step S1007 of FIG. 9). The gate electrode 160 is formed by the sputtering method or the atomic layer deposition method, and is patterned through a photolithography process. The gate insulating layer 150 arranged outside a pattern of the gate electrode 160 may be thinned by etching for forming the gate electrode 160.

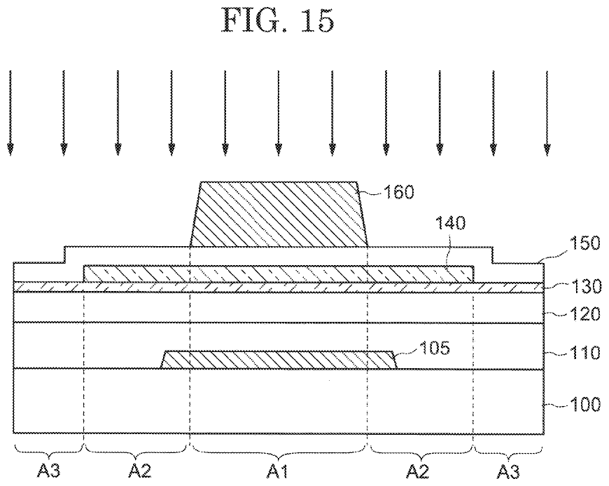

As shown in FIG. 15, the impurities are ion-implanted into the oxide semiconductor layer 140 in a condition that the gate electrode 160 is patterned (“Implanting Impurity Ion” in step S1008 of FIG. 9). Specifically, using the gate electrode 160 as a mask, impurities are implanted into the gate insulating layer 120, the oxide semiconductor layer 140 and the gate insulating layer 150. For example, elements such as boron (B), phosphorus (P), argon (Ar), or nitrogen (N) are implanted into the gate insulating layer 120, the oxide semiconductor layer 140, and the gate insulating layer 150 by ion implantation.

In the oxide semiconductor layer 140 in the second region A2 that does not overlap the gate electrode 160, oxygen defects are generated by ion implantation. The oxide semiconductor layer 140 in the second region A2 is reduced in resistance by trapping hydrogen in the generated oxygen defects. On the other hand, in the oxide semiconductor layer 140 in the first region A1 overlapping the gate electrode 160, impurities are not implanted, so that no oxygen defects are generated and resistance in the first region A1 is not lowered. Through the above steps, the channel region CH is formed in the oxide semiconductor layer 140 in the first region A1, and the source region S and the drain region D are formed in the oxide semiconductor layer 140 in the second region A2.

Dangling bond defects DB are generated in the gate insulating layer 120 and the gate insulating layer 150 in the second region A2 and the third region A3 by the ion implantation. A location and an amount of the dangling bond defects DB can be controlled by adjusting process parameters (for example, dose amount, acceleration voltage, plasma power, and the like) of the ion implantation. In order to sufficiently decrease the resistance values of the oxide semiconductor layer 140 in the source region S and the drain region D, impurity concentration in a vicinity of an upper surface of the oxide semiconductor layer 140 can be adjusted to 1×10¹⁹/cm³ or more by adjusting the process parameters. On the other hand, in the case where an insulating layer containing silicon and nitrogen is used as the gate insulating layer 110, when impurities are implanted into the gate insulating layer 110 at a high concentration, hydrogen generated in the gate insulating layer 110 reaches the oxide semiconductor layer 140, which adversely affects the electrical characteristics of the semiconductor device 10. Therefore, impurity concentration in a vicinity of an upper surface of the gate insulating layer 110 can be adjusted to 1×10¹⁹/cm³ or less.

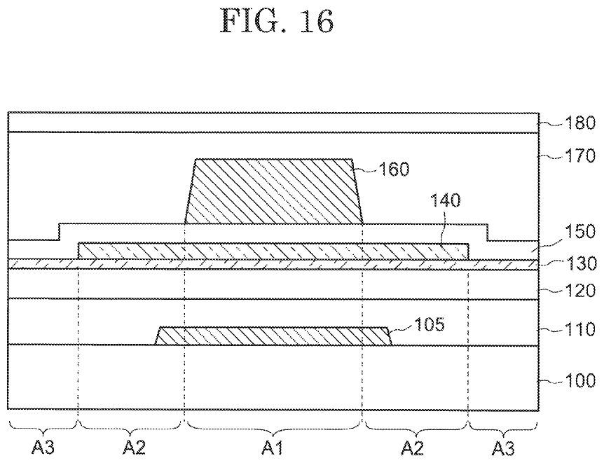

As shown in FIG. 9 and FIG. 16, the insulating layers 170 and 180 are deposited on the gate insulating layer 150 and the gate electrode 160 as interlayer films (“Depositing Interlayer film” in step S1009 of FIG. 9). The insulating layers 170 and 180 are deposited by the CVD method. For example, a silicon nitride layer is formed as the insulating layer 170, and a silicon oxide layer is formed as the insulating layer 180. The materials used as the insulating layers 170 and 180 are not limited to the above. A thickness of the insulating layer 170 is 50 nm or more and 500 nm or less. A thickness of the insulating layer 180 is 50 nm or more and 500 nm or less.

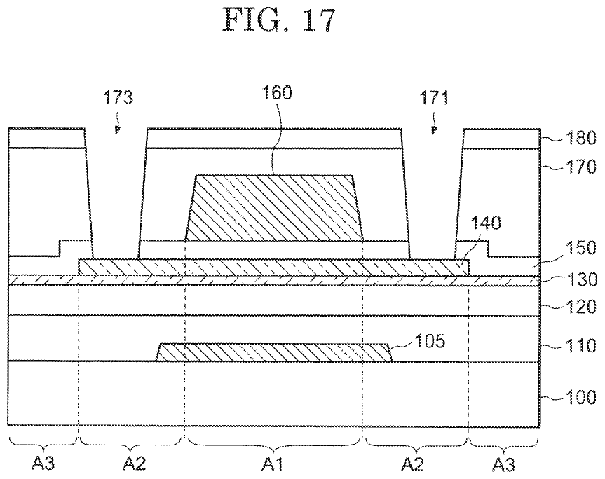

As shown in FIG. 9 and FIG. 17, the openings 171 and 173 are formed in the gate insulating layer 150 and the insulating layers 170 and 180 (“Opening Contact Hole” in step S1010 of FIG. 9). The oxide semiconductor layer 140 in the source region S is exposed by the opening 171. The oxide semiconductor layer 140 in the drain region D is exposed by the opening 173. The semiconductor device 10 shown in FIG. 1 is completed by forming the source-drain electrode 200 on the oxide semiconductor layer 140 exposed by the openings 171 and 173 and on the insulating layer 180 (“Forming SD” in step S1011 of FIG. 9).

### 2. Second Embodiment

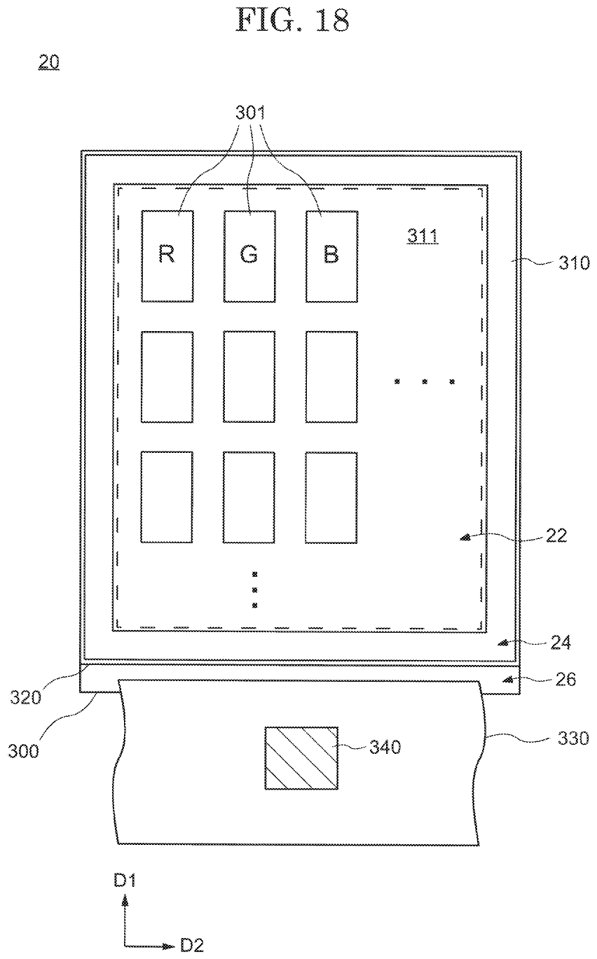

A display device using a semiconductor device according to an embodiment of the present invention will be described with reference to FIG. 18 to FIG. 22. In the embodiment shown below, a configuration in which the semiconductor device 10 described in the first embodiment described above is applied to a circuit of the liquid crystal display device will be described.

### 2-1. Outline of Display Device 20

FIG. 18 is a plan view showing an outline of a display device according to an embodiment of the present invention. As is shown in FIG. 18, the display device 20 includes an array substrate 300, a seal portion 310, a counter substrate 320, a flexible printed circuit substrate 330 (FPC 330), and an IC chip 340. The array substrate 300 and the counter substrate 320 are bonded together by the seal portion 310. A plurality of pixel circuits 301 is arranged in a matrix in a liquid crystal region 22 surrounded by the seal portion 310. The liquid crystal region 22 is a region overlapping a liquid crystal element 311, which will be described later, in a plan view.

A seal region 24 where the seal portion 310 is arranged is a region surrounding the liquid crystal region 22. The FPC 330 is arranged in a terminal region 26. The terminal region 26 is a region where the array substrate 300 is exposed from the counter substrate 320 and is arranged outside the seal region 24. Outside the seal region 24 means regions outside the region where the seal portion 310 is arranged and a region surrounded by the seal portion 310. The IC chip 340 is arranged on the FPC 330. The IC chip 340 supplies a signal for driving each pixel circuit 301.

### 2-2. Circuit Configuration of Display Device 20

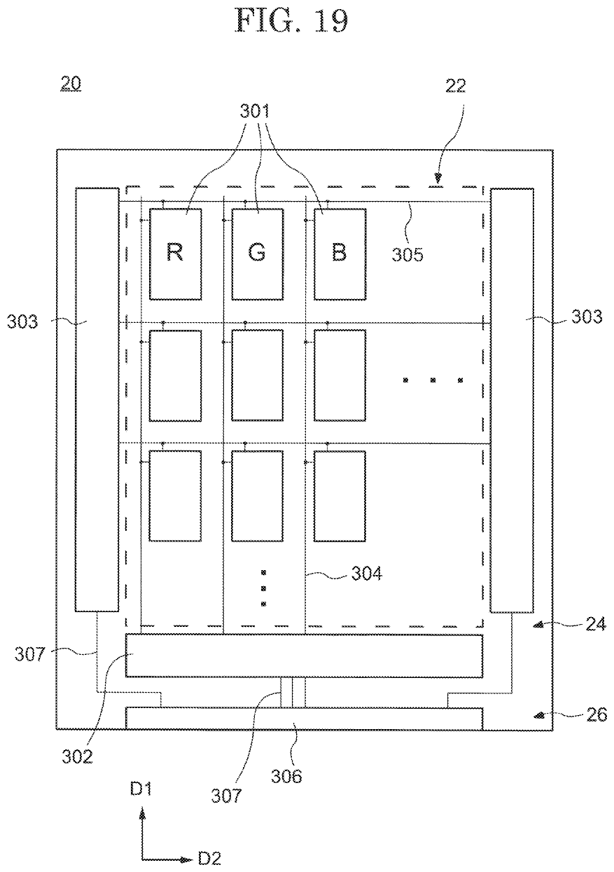

FIG. 19 is a block diagram showing a circuit configuration of a display device according to an embodiment of the present invention. As is shown in FIG. 19, a source driver circuit 302 is arranged at a position adjacent to the liquid crystal region 22 where the pixel circuit 301 is arranged in the direction D1 (column direction), and a gate driver circuit 303 is arranged at a position adjacent to the liquid crystal region 22 in the direction D2 (row direction). The source driver circuit 302 and the gate driver circuit 303 are arranged in the seal region 24 described above. However, the region where the source driver circuit 302 and the gate driver circuit 303 are arranged is not limited to the seal region 24. The source driver circuit 302 and the gate driver circuit 303 may be arranged in any region outside the region where the pixel circuit 301 is arranged.

A source wiring 304 extends from the source driver circuit 302 in the direction D1 and is connected to the plurality of pixel circuits 301 arranged in the direction D1. A gate wiring 305 extends from the gate driver circuit 303 in the direction D2 and is connected to the plurality of pixel circuits 301 arranged in the direction D2.

A terminal portion 306 is arranged in the terminal region 26. The terminal portion 306 and the source driver circuit 302 are connected by a connection wiring 307. Similarly, the terminal portion 306 and the gate driver circuit 303 are connected by the connection wiring 307. Since the FPC 330 is connected to the terminal portion 306, an external device which is connected to the FPC 330 and the display device 20 are connected, and each pixel circuit 301 arranged in the display device 20 is driven by a signal from the external device.

The semiconductor device 10 shown in the first embodiment is used as a transistor included in the pixel circuit 301, the source driver circuit 302, and the gate driver circuit 303.

### 2-3. Pixel Circuit 301 of Display Device 20

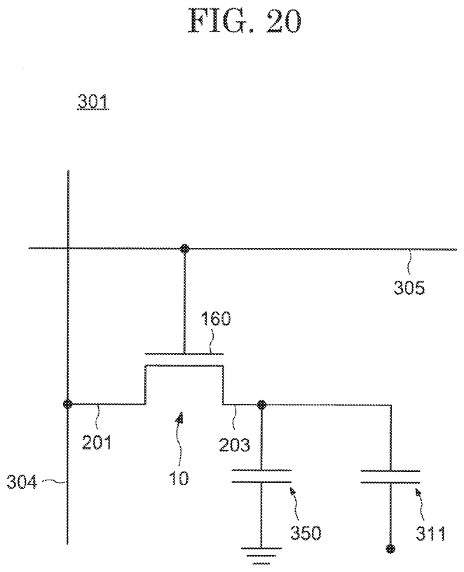

FIG. 20 is a circuit diagram showing a pixel circuit of a display device according to an embodiment of the present invention. As is shown in FIG. 20, the pixel circuit 301 includes elements such as the semiconductor device 10, a storage capacitor 350, and the liquid crystal element 311. The semiconductor device 10 has the gate electrode 160, the source electrode 201, and the drain electrode 203. The gate electrode 160 is connected to the gate wiring 305. The source electrode 201 is connected to the source wiring 304. The drain electrode 203 is connected to the storage capacitor 350 and the liquid crystal element 311. In the present embodiment, although an electrode indicated by “201” is referred to as a source electrode and an electrode indicated by “203” is referred to as a drain electrode for the convenience of explanation, the electrode indicated by “201” may function as a drain electrode and the electrode indicated by “203” may function as a source electrode.

### 2-4. Cross-Sectional Structure of Display device 20

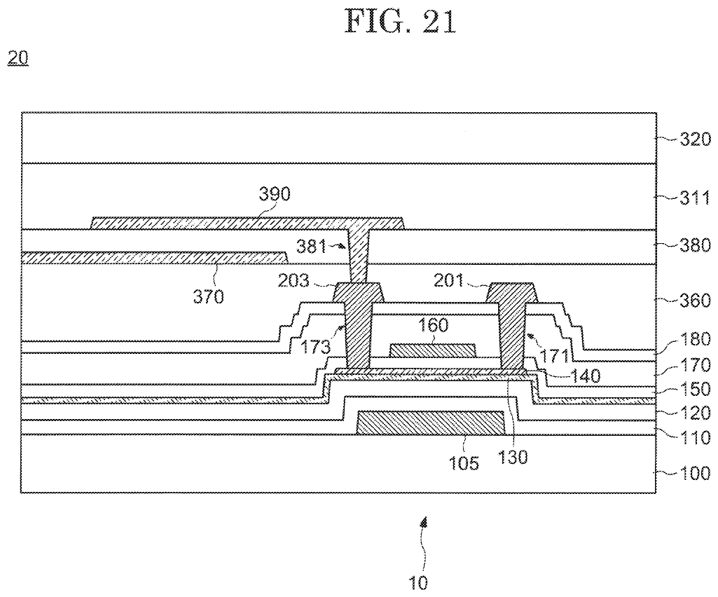

FIG. 21 is a cross-sectional view of a display device according to an embodiment of the present invention. As shown in FIG. 21, the display device 20 is a display device in which the semiconductor device 10 is used. In the present embodiment, although a configuration in which the semiconductor device 10 is used for the pixel circuit 301 is exemplified, the semiconductor device 10 may be used for a peripheral circuit including the source driver circuit 302 and the gate driver circuit 303. In the following description, since the configuration of the semiconductor device 10 is the same as that of the semiconductor device 10 shown in FIG. 1, the description thereof will be omitted.

An insulating layer 360 is arranged on the source electrode 201 and the drain electrode 203. A common electrode 370 arranged in common for the plurality of pixels is arranged on the insulating layer 360. An insulating layer 380 is arranged on the common electrode 370. An opening 381 is arranged in the insulating layers 360 and 380. A pixel electrode 390 is arranged on the insulating layer 380 and within the opening 381. The pixel electrode 390 is connected to the drain electrode 203.

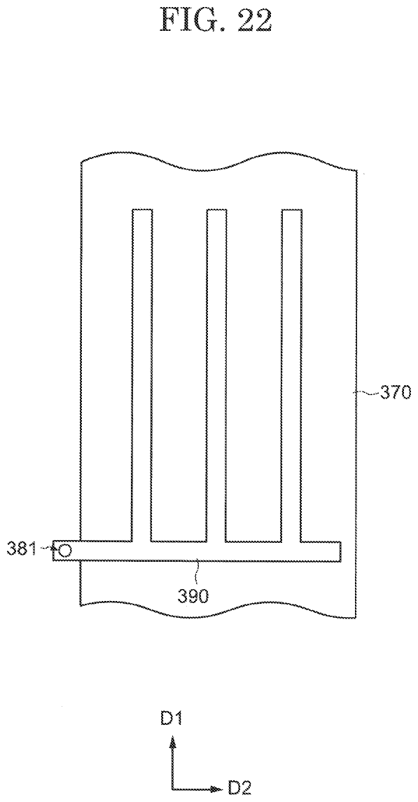

FIG. 22 is a plan view of a pixel electrode and a common electrode of a display device according to an embodiment of the present invention. As shown in FIG. 22, the common electrode 370 has an overlapping region overlapping the pixel electrode 390 in a plan view, and a non-overlapping region not overlapping the pixel electrode 390. When a voltage is supplied between the pixel electrode 390 and the common electrode 370, a horizontal electric field is formed from the pixel electrode 390 in the overlapping region toward the common electrode 370 in the non-overlapping region. A gradation of the pixel is determined by the operation of liquid crystal molecules included in the liquid crystal element 311 by the horizontal electric field.

### 3. Third Embodiment

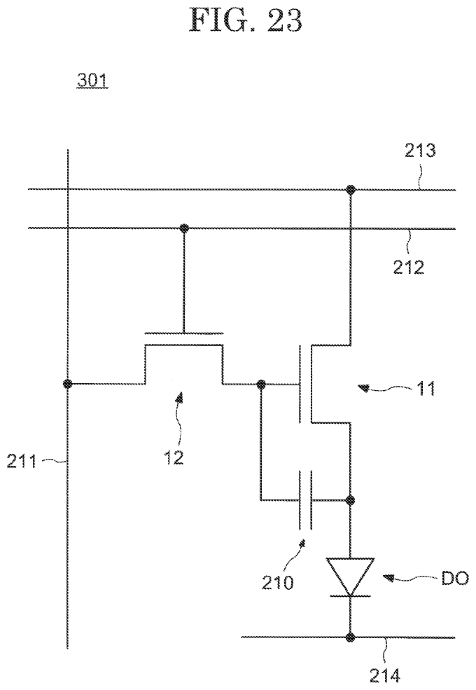

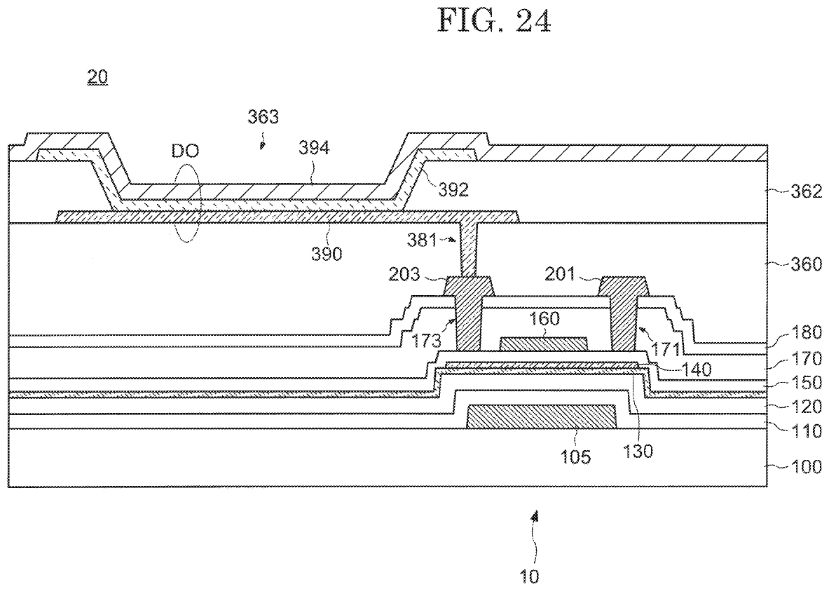

A display device using a semiconductor device according to an embodiment of the present invention will be explained with reference to FIG. 23 and FIG. 24. In the present embodiment, a configuration in which the semiconductor device 10 explained in the first embodiment is applied to a circuit of an organic EL display device will be described. Since the outline and the circuit configuration of the display device 20 are the same as those shown in FIG. 18 and FIG. 19, the description thereof will be omitted.

### 3-1. Pixel Circuit 301 of Display Device 20

FIG. 23 is a circuit diagram showing a pixel circuit of a display device according to an embodiment of the present invention. As shown in FIG. 23, the pixel circuit 301 includes elements such as a drive transistor 11, a selection transistor 12, a storage capacitor 210, and a light-emitting element DO. The drive transistor 11 and the selection transistor 12 have the same configuration as the semiconductor device 10. The source electrode of the selection transistor 12 is connected to a signal line 211, and the gate electrode of the selection transistor 12 is connected to a gate line 212. The source electrode of the drive transistor 11 is connected to an anode power line 213, and the drain electrode of the drive transistor 11 is connected to one end of the light-emitting element DO. The gate electrode of the drive transistor 11 is connected to the drain electrode of the selection transistor 12. The other end of the light-emitting element DO is connected to a cathode power line 214. The storage capacitor 210 is connected to the gate electrode and the drain electrode of the drive transistor 11. A gradation signal for determining light-emitting intensity of the light-emitting element DO is supplied to the signal line 211. A signal for selecting a pixel row in which the gradation signal described above is written is supplied to the gate line 212.

### 3-2. Cross-Sectional Structure of Display Device 20

FIG. 24 is a cross-sectional diagram of a display device according to an embodiment of the present invention. Although the configuration of the display device 20 shown in FIG. 24 is similar to the display device 20 shown in FIG. 21, the configuration above the insulating layer 360 of the display device 20 in FIG. 24 is different from the structure above the insulating layer 360 of the display device 20 in FIG. 21. Hereinafter, in the configuration of the display device 20 in FIG. 24, descriptions of the same configuration as the display device 20 in FIG. 21 are omitted, and differences between the two will be explained.

As shown in FIG. 24, the display device 20 has the pixel electrode 390, a light-emitting layer 392, and a common electrode 394 (the light-emitting element DO) above the insulating layer 360. The pixel electrode 390 is arranged above the insulating layer 360 and inside the opening 381. An insulating layer 362 is arranged above the pixel electrode 390. An opening 363 is arranged in the insulating layer 362. The opening 363 corresponds to a light-emitting region. That is, the insulating layer 362 defines a pixel. The light-emitting layer 392 and the common electrode 394 are arranged above the pixel electrode 390 exposed by the opening 363. The pixel electrode 390 and the light-emitting layer 392 are individually arranged for each pixel. On the other hand, the common electrode 394 is arranged in common for the plurality of pixels. Different materials are used for the light-emitting layer 392 depending on a display color of the pixel.

In the second embodiment and third embodiment, although the configuration in which the semiconductor device explained in the first embodiment was applied to a liquid crystal display device and an organic EL display device was exemplified, the semiconductor device may be applied to display devices (for example, a self-luminous display device or an electronic paper display device other than an organic EL display device) other than these display devices. In addition, the semiconductor device described above can be applied without any particular limitation from a small sized display device to a large sized display device.

Each of the embodiments described above as an embodiment of the present invention can be appropriately combined and implemented as long as no contradiction is caused. In addition, the addition, deletion, or design change of components, or the addition, deletion, or condition change of processes as appropriate by those skilled in the art based on a semiconductor device and a display device of each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first gate electrode;
a first insulating layer on the first gate electrode;
an oxide semiconductor layer on the first insulating layer;
a second insulating layer on the oxide semiconductor layer; and
a second gate electrode on the second insulating layer,
wherein
the first insulating layer includes a first layer including silicon and nitrogen, a second layer including silicon and oxygen, and a third layer including aluminum and oxygen,
a thickness of the first layer is 10 nm or more and 190 nm or less,
a thickness of the second layer is 10 nm or more and 100 nm or less,
a total thickness of the first layer and the second layer is 200 nm or less, and
a thickness of the third layer 1 nm or more and 10 nm or less.

2. The semiconductor device according to claim 1, wherein
the second layer is arranged on the first layer, and
the third layer is arranged on the second layer.

3. The semiconductor device according to claim 2, wherein
the oxide semiconductor layer is polycrystalline.

4. The semiconductor device according to claim 3, wherein
impurity concentration in a vicinity of an upper surface of the oxide semiconductor layer is 1×10¹⁹/cm³ or more.

5. The semiconductor device according to claim 4, wherein
impurity concentration in a vicinity of an upper surface of the first layer is 1×10¹⁹/cm³ or less.

6. The semiconductor device according to claim 2, wherein
the thickness of the first layer is 10 nm more and 100 nm or less.

7. The semiconductor device according to claim 2, wherein
the total thickness of the first layer and the second layer is 150 nm or less.

8. The semiconductor device according to claim 1, wherein
a thickness of the second insulating layer is 10 nm or more and 75 nm or less.

9. The semiconductor device according to claim 2, wherein
the thickness of the first layer is 10 nm or more and 100 nm or less,
the thickness of the second layer is 10 nm or more and 50 nm or less,
the total thickness of the first layer and the second layer is 150 nm or less.

10. The semiconductor device according to claim 2, wherein
a thickness of the second insulating layers is 10 nm or more and 100 nm or less.
